(19) United States
(12) Patent Application Publication
(10) Pub. No.: US 2025/0326655 A1
(43) Pub. Date: Oct. 23, 2025

(54) DOPED RARE EARTH-CONTAINING MATERIALS AND THEIR PROPERTIES

(71) Applicant: Unearthly Materials, Inc., Rochester, NY (US)

(72) Inventors: Liyanagamage Ranganath Dias, Rochester, NY (US); Sergio Villa-Cortes, Rochester, NY (US); Nugzari Khalvashi-Sutter, Rochester, NY (US); Bo Zheng, Rochester, NY (US); Gustav Michael Borstad, Rochester, NY (US)

(21) Appl. No.: 19/071,642

(22) Filed: Mar. 5, 2025

Related U.S. Application Data
(60) Provisional application No. 63/562,192, filed on Mar. 6, 2024.
(60) Provisional application No. 63/746,122, filed on Jan. 16, 2025.

(51) Int. Cl. C01F 17/30

(52) U.S. Cl. CPC C01F 17/30; C01P 2002/30; C01P 2002/54; C01P 2002/72; C01P 2002/82; C01P 2004/38; C01P 2006/40; C01P 2006/42

(57) ABSTRACT

A system including a material is described. The material includes at least one rare earth (R), hydrogen (H), and at least one dopant (D). The material includes R, H, and D with R:H:D in a ratio of 1:x:y, where x is greater than 2 and less than 3, and y is at least 0.4 and less than 1.

### CROSS REFERENCE TO OTHER APPLICATIONS

This application claims priority to U.S. Provisional Patent Application No. 63/562,192 entitled RARE EARTH-CONTAINING MATERIALS AND THEIR PROPERTIES filed Mar. 6, 2024 and U.S. Provisional Patent Application No. 63/746,122 entitled RARE EARTH NITRIDES AND HYDRIDES AND THEIR PROPERTIES filed Jan. 16, 2025, both of which are incorporated herein by reference for all purposes.

### BACKGROUND OF THE INVENTION

Rare earths, such as scandium, yttrium, lutetium, lanthanum, and ytterbium, are of interest for a variety of reasons. Rare earths are usable in various technologies due to their properties, such as their thermal, magnetic, and electrical characteristics. Compounds including rare earths may be of particular interest. For example, yttrium barium copper oxide (YBCO, or YBa₂Cu₃O₇) is a high temperature superconductor. Yttrium may also be used in yttrium aluminum garnet (YAG) lasers, as well as in ceramics and alloys. Similarly, scandium may be used in alloys for aerospace and other applications, in solid oxide fuel cells, as well as in other applications. Lutetium may also be used in lenses, as catalysts, in LEDs, and for other technologies, Other rare earths may have other applications. Ongoing developments may identify new uses for materials containing rare earths. The applications for which rare earths may be used may depend upon the crystal structure of the materials that include the rare earths, which influences the electrical, magnetic, and mechanical properties of these materials. Consequently, techniques for investigating the structure and resulting characteristics of materials including rare earths are desired.

### BRIEF DESCRIPTION OF THE DRAWINGS

Various embodiments of the invention are disclosed in the following detailed description and the accompanying drawings.

FIGS. 1A-1B are a diagram indicating the crystal structure of an embodiment of a doped rare earth hydride.

FIGS. 2A-2D depict embodiments of x-ray and Raman spectra corresponding to a rare earth-containing material such as nitrogen doped lutetium hydride.

FIGS. 3A-3C depict graphs of temperature dependent DC magnetic susceptibility data corresponding to a rare earth-containing material such as nitrogen doped lutetium hydride.

FIGS. 4A-4D are graphs indicating various electrical transport measurements corresponding to an embodiment of rare earth-containing material(s), such as nitrogen doped lutetium hydride, and the transition temperature versus varying doping levels for such rare earth-containing material(s).

FIG. 5 depicts an embodiment of a cell of a form of a rare earth hydride.

FIG. 6 depicts an embodiment of a cell of a form of a rare earth hydride.

FIG. 7 is a diagram depicting an embodiment a cell indicating the crystal structure of an embodiment of a rare earth nitride.

FIGS. 8A-8C depict embodiments of Raman spectra corresponding to a rare earth-containing material such as sub-stoichiometric lutetium nitride.

FIGS. 9A-9C depict graphs of temperature dependent DC magnetic susceptibility data corresponding to a rare earth-containing material such as sub-stoichiometric lutetium nitride.

FIG. 10 is a flow chart depicting an embodiment of a method for fabricating rare earth-containing material(s).

FIG. 11 is a flow chart depicting an embodiment of a method for fabricating rare earth-containing material.

FIGS. 12A-12D depict embodiments of method for fabricating rare earth-containing material(s).

FIG. 13 is a flow chart depicting an embodiment of a method for fabricating precursor material(s) rare earth-containing material.

FIG. 14 is a flow chart depicting an embodiment of a method for fabricating precursor material(s) rare earth-containing material.

### DETAILED DESCRIPTION

The invention can be implemented in numerous ways, including as a process; an apparatus; a system; a composition of matter; a computer program product embodied on a computer readable storage medium; and/or a processor, such as a processor configured to execute instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a memory described as being configured to perform a task may be implemented as a general component that is temporarily configured to perform the task at a given time or a specific component that is manufactured to perform the task. As used herein, the term ‘processor’ refers to one or more devices, circuits, and/or processing cores configured to process data, such as computer program instructions.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

Rare earths are of use in a number of applications. The applications for which rare earths may be used depend upon the properties (e.g., electrical, magnetic, and/or mechanical properties) of the materials incorporating the rare earths. These properties depend upon the structures of the materials. The structure (e.g., the crystal structure) may depend upon the rare earth(s) used, as well as the elements with which the rare earth(s) are combined. Further, changes in the structure of the materials due to the addition of other elements (e.g., doping) may result in changes to the characteristics of the materials. Consequently, techniques for investigating the structure and resulting characteristics of materials including rare earths are desired.

A system including a material is described. The material includes at least one rare earth (R), hydrogen (H), and at least one dopant (D). The material includes R, H, and D with R:H:D in a ratio of 1:x:y, where x is greater than 2 and less than 3, and y is at least 0.4 and less than 1. In some embodiments, the material is present at least in a temperature range of at least twenty degrees Celsius and not more than one hundred degrees Celsius and in a pressure range of at least one half atmosphere and not more than 1.5 atmospheres of pressure. In some embodiments, the material is present in a much larger range of temperatures and/or pressures. For example, the material may be present in temperatures as low as 273K, 100 K, 50K, or 5K and to temperatures as high as 300° C., 400° C., 500° C., 600° C., or 700° C. Similarly, the material may be present down to a few millibars of pressure. The material may also be present in higher pressures, for example up to at least 2 atmospheres, 3 atmospheres, 10 atmospheres of pressure, or higher. In some embodiments, R is a single rare earth and the dopant, D, is a single dopant. In some embodiments, R is lutetium, and D is nitrogen. The material may have a crystal structure and a stoichiometry RHₓD_{y} (e.g., LuHₓN_{y}). In some such embodiments, x is at least 2.1 and not more than 2.4 and y is at least 0.7 and not more than 0.8.

The crystal structure of the material may have face-centered cubic positions, tetrahedral positions, and octahedral positions in a cell. In such embodiments, the face-centered cubic positions include R atoms, the tetrahedral positions include H atoms, and the octahedral positions include both the H atoms and D atoms. In some such embodiments, a portion of the octahedral positions, the face-centered cubic positions, and/or the tetrahedral positions have at least one vacancy. Further, the material may have a lattice parameter that depends on x and y.

The material may be present (e.g., in the temperature range(s) and/or the pressure range(s) described) with at least one additional material. The additional material(s) may also include the rare earth(s). For example, the material LuHₓN_{y} may be present along with LuH₂ and/or LuH₃. Further, the material may take on forms such as a powder, a bulk sample, or a thin film residing on a substrate and having a thickness of at least ten nanometers and not more than three micrometers. In some embodiments, the material may also include least one of O and Si (e.g., RHₓD_{y}OᵤSi_{w}, where u and w may be small, for example, u, w<0.1).

A system including a material is described. The material includes at least one rare earth (R) and nitrogen (N). The material includes R and N with R:N in a ratio of 1:y, where y is greater than zero and less than one. In some embodiments, the material is present at least in the temperature range(s) and pressure range(s) described herein. The material may have a crystal structure and a stoichiometry RN_{y} (e.g., LuN_{y}). In such embodiments, y is greater than 0 and less than one. In some embodiments, y is greater than 0.6 and less than 0.9. The crystal structure of the material may have face-centered cubic positions and octahedral positions. The face-centered cubic positions include R atoms and the octahedral positions include N atoms. A portion of the octahedral positions have at least one vacancy.

A method is described. The method includes providing at least one precursor material and providing, using the precursor material(s), a material including at least one rare earth (R), hydrogen (H); and a dopant (D). The material includes R, H, and D in a ratio of 1:x:y, where x is zero or greater than 2 and less than 3, and y is at least 0.4 and less than 1. For y=0, D may be nitrogen N. For example, R may be lutetium, D may be nitrogen (e.g., LuN_{y} where 0<y<1) and the precursor material(s) may be selected from LuH₂ or LuH₃.

In some embodiments, providing the material from the precursor material(s) includes annealing the precursor material(s) in a D-containing gas at temperature(s) greater than a decomposition temperature of the precursor material(s). Where x is greater than 2 and less than 3, the providing the material further includes reducing the temperature to within a temperature range below the decomposition temperature of the precursor material(s). The temperature range is greater than one hundred degrees Celsius and less than the decomposition temperature. The method also includes annealing at temperature(s) within the temperature range. In some embodiments, providing the precursor material(s) includes obtaining premade precursor material(s). In some embodiments, providing the precursor material(s) include synthesizing the precursor material(s). For example, fcc (face centered cubic)-LuH₂ and hcp (hexagonal close pack)-LuH₃ may be synthesized from Lu and hydrogen gas. In some embodiments, providing the material further includes depositing the material using the at least one precursor material as a deposition source.

The techniques are described in the context of the rare earth lutetium, nitrogen, and hydrogen. For example, nitrogen doped lutetium hydride (which might also be considered hydrogen doped lutetium nitride) is discussed. One of ordinary skill in the art will recognize that the techniques described may be applied to other rare earths and, in some embodiments, other elements and/or dopants. Further, specific configurations are described and depicted for clarity. One of ordinary skill in the art will recognize that other configurations may be possible. For example, particular stoichiometries are specifically discussed. Other analogous stoichiometries may be possible.

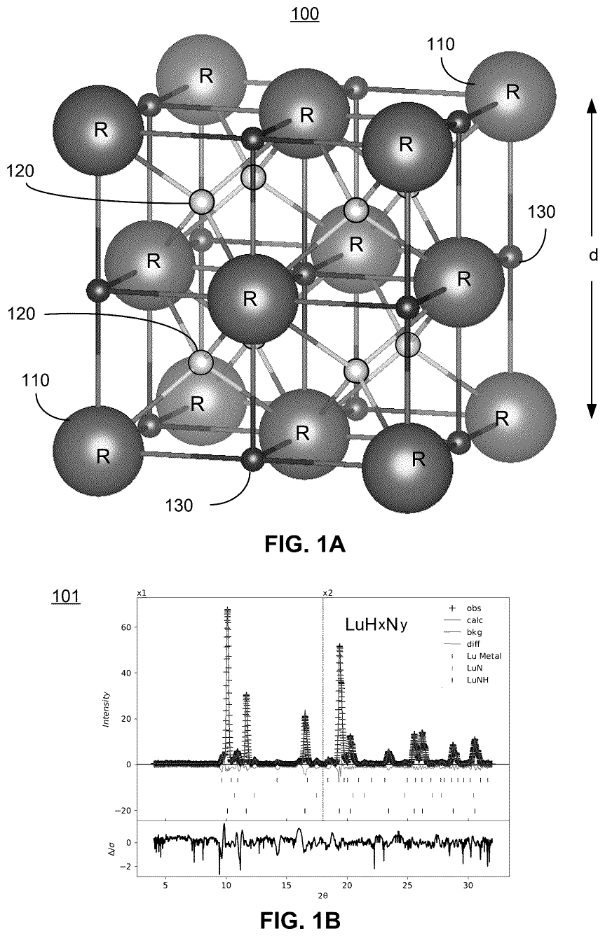

FIGS. 1A-1B describe an embodiment of a rare earth-containing material. FIG. 1A depicts a three-dimensional view of the structure of cell 100 for an embodiment of rare earth-containing material. Thus, some portions of cell 100 may be obscured. Further, FIG. 1A is not to scale. FIG. 1B is a graph depicting x-ray diffraction spectrum 101 for one embodiment of the rare earth-containing material. In some embodiments, cell 100 is for a material including a rare earth (R), an additional element such as hydrogen (H), and a dopant (D) such as nitrogen. Thus, cell 100 may be considered to be a cell for nitrogen doped lutetium hydride. As such, the term rare earth-containing material when used in the context of cell 100 may be considered to be nitrogen doped lutetium hydride, and vice versa. In other embodiments, other and/or multiple rare earths, multiple additional elements and/or other and/or multiple dopants may be present in cell 100. For example, rare earths (R) such as ytterbium, yttrium, cerium, lanthanum, scandium, and/or thulium might be used in addition to or in lieu of lutetium as R. Alloys including rare earth(s) may also be used as or included in R. For example, yttrium-zirconium and/or yttrium-strontium alloys might be used. Similarly, boron, zirconium, tungsten, strontium, and/or small amounts of oxygen might be used in addition to or in lieu of nitrogen as D.

In some embodiments, the rare earth-containing material corresponding to cell 100 includes R, H, and D in a ratio of 1:x:y=R:H:D, where x is greater than 2 and less than 3, and y is at least 0.4 and less than 1. In some embodiments, this may be considered to form the material RHₓD_{y}, where 2<x<3 and 0.4≤y<1. Consequently, the rare earth-containing materials are discussed in this context (e.g., RHₓD_{y}, LuHₓN_{y}, etc.). For example, the material may be LuHₓN_{y}, where x and y have the values indicated. In some embodiments, x is greater than 2 and not more than 2.8 and y is at least 0.6 and less than 1. In some embodiments, x is greater than 2 and not more than 2.4. In some embodiments, x is at least 2.1 and not more than 2.3 (e.g., nominally 2.2). In some embodiments, y is at least 0.5 and less than 1. In some such embodiments, y is at least 0.6. In some such embodiments, y is at least 0.7. In some embodiments, y is not more than 0.9. In some embodiments, y is at least 0.65 and not more than 0.9 (e.g., nominally 0.7-0.8, or 0.71-0.75). For example, in some embodiments, x may be greater than 2.1 and not more than 2.3 and y may be at least 0.7 and not more than 0.8. Other analogous stoichiometries are possible. Thus, in some embodiments, x+y is less than or equal to 3.

The rare earth-containing material corresponding to cell 100 is also stable at ambient conditions. As used herein, “stable” indicates that the material is present and can. but need not, include the material being nonreactive. In some embodiments, the rare earth-containing material is stable/present at least in a temperature range of at least twenty degrees Celsius and not more than one hundred degrees Celsius and in a pressure range of at least one half atmosphere and not more than 1.5 atmospheres of pressure (e.g., at ambient/room temperature and pressure). In some embodiments, the material is stable (e.g., present) in a much larger range of temperatures and/or pressures. For example, the material may be present in temperatures as low as 273K, 100 K, 50K, or 5K and to temperatures as high as 300° C., 400° C., 500° C., 600° C., or 700° C. Similarly, the material may be present down to a few millibars of pressure. The material may also be present in higher pressures, for example up to at least 2 atmospheres, 3 atmospheres, 10 atmospheres of pressure, or higher.

Cell 100 may have three types of sites, or positions, 110, 120, and 130. For simplicity, only some positions 110, 120, and 130 are labeled. Positions 110 are locations at which atoms of the rare earth material(s) (R) may be located. Thus, rare earth positions (R positions) 110 are labeled R and are shown as large, darkly shaded spheres. Rare earth positions 110 are at face-centered cubic locations in cell 100. Thus, cell 100 is termed a face-centered cubic (FCC) cell. In some embodiments, therefore, the rare earth-containing material is an FCC material. In general, all of R positions 110 are occupied by rare earth atoms (e.g., Lu atoms). However, one of ordinary skill in the art will recognize that in a macroscopic sample, composed of a large number of cells 100, there may be some defects. For example, there may be vacancies for which a rare earth atom is missing from particular R position(s) 110. However, such defects may not be sufficient to affect the stoichiometry and/or material properties.

Cell 100 also includes tetrahedral positions 120 (indicated by lighter circles) and octahedral positions 130 (indicated by darker circles). In some embodiments, hydrogen atoms reside in tetrahedral locations 120. For octahedral positions 130, a nitrogen atom or a hydrogen atom may be present. If all tetrahedral positions 120 and octahedral positions 130 were occupied by hydrogen atoms, then cell 100 may have the formula RH₃. Similarly, if all tetrahedral positions 120 and all octahedral positions 130 were occupied by H and/or D, then for cell 100 RHₓD_{y}, x+y=3.

In some embodiments the rare earth-containing material described by cell 100 is sub-stoichiometric. Stated differently, for the rare earth-containing material corresponding to cell 100, RHₓD_{y}, x+y<3. Consequently, x and y have the ranges indicated above. For example, for lutetium, hydrogen, and nitrogen, the rare earth-containing material is LuHₓN_{y}, where x is greater than 2 and not more than 2.8 and y is at least 0.6 and less than 1 (i.e. 2<x+y<3). In some embodiments, the rare earth material may be LuH_{2-2.4}N_{0.7-0.8} or LuH_{2.1-2.3}N_{0.7-0.74}. Thus, in some embodiments, not all octahedral positions 130 include nitrogen atoms or hydrogen atoms. Similarly, in some embodiments, hydrogen atoms may not be present at all tetrahedral positions 130. Consequently, the rare earth-containing material LuHₓN_{y} for cell 100 is sub-stoichiometric.

In addition to being of interest for its own properties, the rare earth-containing material for cell 100 may be used to investigate the effects of changes in stoichiometry and/or composition for rare earth-containing materials. For example, for the material LuHₓN_{y} with x and y in the ranges described herein (e.g., LuH_{2-2.8}N_{0.6-0.9}), changes in the stoichiometry may affect the lattice parameter, d, as well as other properties. Further, LuHₓN_{y} may be compared with LuN (i.e. x=0, y=1), LuH₂ (i.e. y=0, x=2) and/or LuH₃(i.e. y=0, x=3). LuN, LuH₂, and LuH₃ are commercially available or may be fabricated. Thus, the properties of LuHₓN_{y}, where x and y have the ranges above (including 2<x+y<3), may be compared to the properties of LuN, LuH₂, and/or LuH₃ to investigate the effects that changes in stoichiometry may have on the crystal structure and other properties of a rare earth-containing materials. In addition, LuN, LuH₂, and/or LuH₃ may be used to fabricate LuHₓN_{y} for an improved analysis.

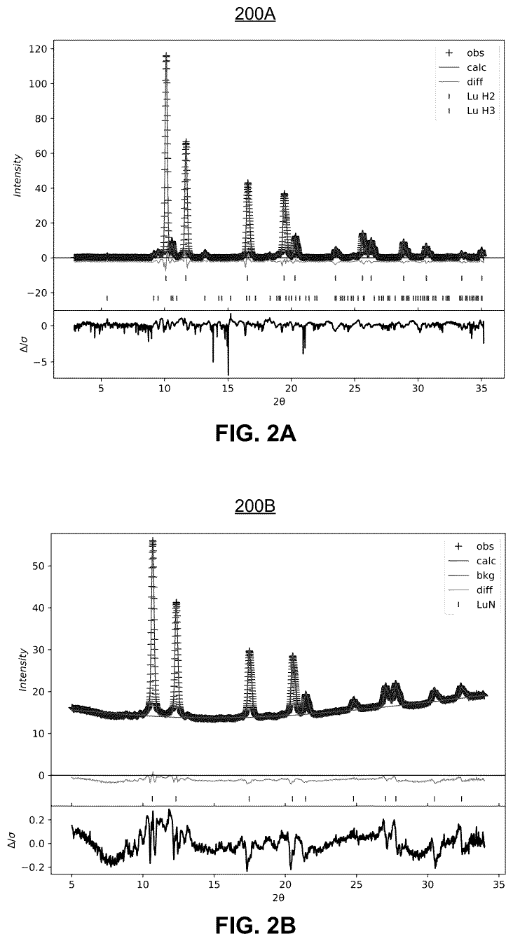

For example, lattice parameters and crystal structure may be determined using x-ray diffraction. Comparisons of lattice parameters for similar, arguably related structures may be made based on the results of x-ray diffraction characterizations. FIG. 1B depicts a graph of one embodiment of x-ray diffraction spectrum 101 for LuHₓN_{y}. For LuHₓN_{y} corresponding to cell 100, the lattice parameter d may be in the range of 5.04 to 5.07 Å, based on x-ray diffraction measurements. For example, for LuH_{2.1-2.3}N_{0.71-0.73} (FCC with Fm-3m) the lattice parameter is approximately 5.065 Å. This can be contrasted with known or calculated values for LuN, LuH, LuH₂, and/or LuH₃. For example, LuH₂ is known to be cubic (e.g., FCC with Fm-3m) and to have a lattice parameter of 5.029 to 5.033 Å. See, e.g., FIG. 2A, described below. Similarly, LuH₃ is known to have a lattice parameter of approximately 5.12 to 5.156 Å for the cubic (FCC) form. See, e.g., FIG. 2B, described below. Stoichiometric LuN is known to have a cubic, rock-salt structure having a lattice parameter of 4.75 to 4.76 Å. Finally, LuH, which also has a rock-salt structure, is known to have a theoretical lattice parameter of 4.80 Å. Thus, the lattice parameter of LuHₓN_{y} corresponding to cell 100 is closer in size to the lattice parameters of similar materials (e.g., LuH₂ and LuH₃) having a similar crystal structure (e.g., FCC as opposed to rock-salt). However, the lattice parameter of LuHₓN_{y} corresponding to cell 100 is larger than that of fcc-LuH₂ and smaller fcc-LuH₃ despite the lattice parameter of LuN being significantly smaller.

These differences in lattice parameters might be understood as follows. When nitrogen is introduced into the octahedral positions 130 of cell 100 (e.g., having a cubic Fm-3m structure), the effect on the lattice parameter may depend on several factors, including the size of the nitrogen atoms compared to the hydrogen atoms (e.g., for LuHₓN_{y} compared to LuH₂) and the specific electronic interactions that occur in the resulting compound. In general, if additional atoms are added to the interstices of the lattice, the lattice may expand. Thus, an expansion of the crystal structure and a larger lattice parameter may result for LuH₂ transitioning to LuH₃. Conversely, if the incorporation of the atom leads to stronger bonding interactions, it could lead to a contraction of the crystal structure and a smaller lattice parameter. If the nitrogen atoms are larger than the hydrogen atoms being replaced and if the incorporation of nitrogen in to the tetrahedral sites allows the lattice to expand more freely, then the lattice parameter may be expected to increase for the nitrogen occupying tetrahedral position. In the case of LuHₓN_{y}, however, the introduction of nitrogen into the lattice (e.g., as compared to LuH₂ and LuH₃) appears to result in an intermediate the lattice parameter. More specifically, for a transition from FCC-LuH₂ to FCC-LuH₃, the lattice expansion is due to the addition of hydrogen to the interstices of the lattice. Thus, the fcc-LuH₃ lattice parameter may be around 5.12 to 5.156 Å. However, when nitrogen is introduced to octahedral positions, the strong electronegativity of nitrogen may cause the lattice to contract. As a result, the lattice parameter for LuHₓN_{y} is in the range described (e.g., approximately 5.04 to 5.07 Å).

In some embodiments, the rare earth-containing material of interest (e.g., LuHₓN_{y} where x and y are in the ranges described, e.g., 2<x<3 and 0.5≤y<1) may be mixed with other materials. This may occur due to the fabrication process(es) utilized. Thus, LuHₓN_{y} may be present in combination with another material that includes a rare earth (e.g., Lu). For example, in some cases, LuHₓN_{y} is fabricated from LuH₂ and nitrogen gas. The LuH₂ may not fully covert to LuHₓN_{y}. For example, if LuHₓN_{y} is formed from a bulk sample (e.g., a large chunk) of LuH₂ less LuHₓN_{y} may be formed. For finer powders, a higher fraction of the LuH₂ may be converted to LuHₓN_{y}. In some cases, the majority phase may be LuHₓN_{y}. For thin film technologies, it may be possible to provide thin films (e.g., by co-deposition or deposition of multilayers at elevated temperatures or at room temperature followed by an anneal) that have a majority of LuHₓN_{y} or LuHₓN_{y} in isolation (e.g., a very high fraction of or only LuHₓN_{y}). In such cases, x-ray diffraction may be used to determine whether LuHₓN_{y} exists in isolation or with other materials as well as the composition of the other materials. For example, x-ray diffraction may indicate that a portion of the material has a different lattice parameter than that of LuHₓN_{y}. As such, x-ray diffraction may be used in conjunction with other techniques to investigate the structural properties of LuHₓN_{y} and compare these properties with other rare earth-containing materials. Consequently, fabrication techniques and/or the suitability of LuHₓN_{y} (or other rare earth-containing materials) for particular applications may be evaluated.

In addition to the crystal structure (e.g., FCC versus rock-salt), the stoichiometry and/or locations of individual atoms within the cell 100 are desired to be determined and compared to other similar rare earth-containing materials. For example, a determination of which atoms are at positions 110, 120, and 130 is desired determined and compared to the positions of corresponding atoms in analogous rare earth-containing materials. Similarly, the effects of variations in stoichiometry (e.g., LuH_{2δ}N_{1-ε} where δ and ε may vary and are small) are also desired to be investigated. For example, R atoms (Lu atoms) may be at R positions 110 (i.e. FCC locations), H atoms may be at tetrahedral positions 120, and a mix of H atoms and N atoms may be at octahedral positions 130 (with some vacancies—not expressly indicated in cell 100). Other than the size of the lattice parameter, this structure may be indistinguishable from materials such as LuH₂, LuH₃ and/or LuN using X-ray spectroscopy. Thus, X-ray diffraction alone may be inadequate for such studies. However, the stoichiometry might be determined using Raman spectroscopy. Such material(s) may have interesting properties for crystal lattice studies, such as a different lattice parameter and/or different electronic structure properties.

In some embodiments, Raman spectroscopy is the desired technique for accurately determining the stoichiometry of the rare earth-containing material. Raman spectroscopy may be particularly useful where nitrogen doped lutetium hydride (or other analogous doped rare earth hydride) is mixed with other stoichiometries. The lattice constant of the nitrogen doped rare earth hydride (e.g., LuHₓN_{y}) changes based upon the stoichiometry. Similarly, the lattice constant of the LuHₓN_{y} may change with the addition of other materials, such as oxygen. In some embodiments, the fabrication process may result in O and/or Si (in some cases trace amounts thereof) being present. Raman spectroscopy may also be used to identify changes in stoichiometry (e.g., changes in x and/or y, or the presence of vacancies) or the presence of such materials. In some such embodiments, the rare earth-containing material may take the form RHₓD_{y}D2_{w}, where D2 is O and/or Si and w is less than 0.3 (e.g., 0≤w<0.3)

For example, FIGS. 2A-2D depict graphs 200A, 200B, 200C, and 200D corresponding to LuH₂, LuH₃, and embodiments of a rare earth-containing material such as LuHₓN_{y}. The analysis herein may apply to other analogous rare earth-containing materials such as RHₓD_{y}. FIG. 2A depicts graph 200A of x-ray diffraction data for LuH₂ and minor amount of hcp-LuH3. FIG. 2B depicts graph 200B of x-ray diffraction data for LuN. Although lattice parameter and other characteristics of LuH₂ and LuN may be determined from such spectra, some structural features of rare earth-containing materials may not be resolved with such techniques.

FIG. 2C depicts graph 200C of Raman spectra 200C-1 and 200C-2 for two stoichiometries of LuHₓN_{y} (i.e. LuHₓ₁N_{y1} and LuHₓ₂N_{y2}). Differences in spectra 200C-1 and 200C-2 correspond to differences in stoichiometries despite the presence of the same constituent atoms (e.g., Lu, H, and N). FIG. 2D depicts graph 200D of a Raman spectrum with regions corresponding to positions 120 and 130 of cell 100 for LuHₓN_{y}. In particular, octahedral bands corresponding to H atoms and N atoms residing at octahedral positions 130 and a tetrahedral band corresponding to H atoms residing at tetrahedral positions 120 are shown. The octahedral H band may be understood as H atoms replacing N atoms at octahedral locations 130, which may create vacancies. A nitrogen vacancies band corresponding to vacancies for nitrogen atoms at octahedral positions 130 are also indicated. As such, for the particular sample shown, it is indicated that tetrahedral positions 120 are fully occupied by hydrogen atoms (H^{T}₂, where T indicates tetrahedral positions) while octahedral positions 130 are occupied by both hydrogen and nitrogen atoms, but that vacancies do exist (H^{O}_{ε}N^{O}_{ε}, where ε+δ<1). Stated differently, cell 100 may not have octahedral sites 130 full filled by H and/or N. In some cases, vacancies in tetrahedral positions 120 and/or rare earth/FCC positions 110, if present, may also be identified.

Thus, using Raman spectroscopy and x-ray diffraction, the structural characteristics of rare earth-containing materials corresponding to cell 100 may be studied and identified. For example, the lattice parameter and positions of the atoms R, H, and D (e.g., Lu, H, and N) for RHₓD_{y} (e.g., LuHₓN_{y}), where x and y are in the ranges described herein, may be determined. Slight variations in stoichiometry, for example LuHₓN_{y} being sub-stoichiometric (including N and/or H vacancies) may be determined. Further, as discussed herein, the structural properties of RHₓD_{y} may be compared with known and/or new rare earth-containing materials. As such, identification of materials that may be suitable for applications of rare earths may be facilitated.

The structure of a material typically influences other properties of the material. For example, electronic, magnetic, and/or mechanical properties of a material may be determined in whole or in part by its crystal structure. Thus, other properties of rare earth-containing materials generally, such as RHₓD_{y}, may be investigated using a particular material, such as LuHₓN_{y}.

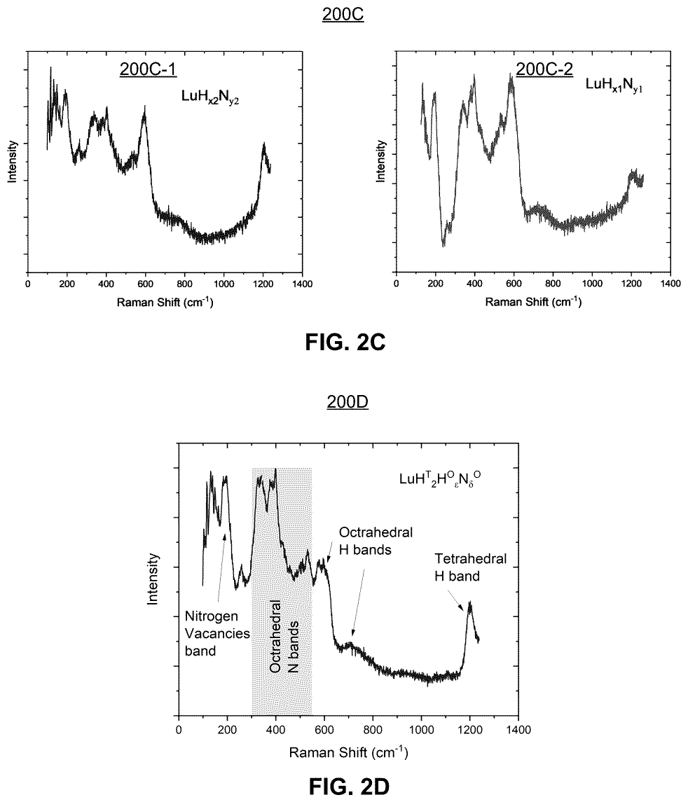

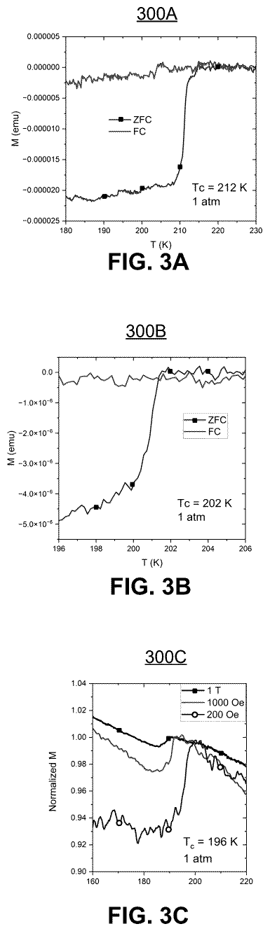

FIGS. 3A-3C depict graphs 300A, 300B, and 300C of magnetic data for LuHₓN_{y}, with x and y in the ranges described herein. Similarly, FIGS. 4A-4D depict graphs 400A, 400B, and 400C relating to electrical transport of for LuHₓN_{y}, with x and y in the ranges described herein. FIG. 4D depicts the transition temperature for embodiments of LuHₓN_{y} having varying doping levels. Graphs 300A, 300B, and 300C depict magnetic moment versus temperature for LuHₓN_{y} taken using a SQUID magnetometer (e.g., an MPMS SQUID magnetometer). As indicated in graphs 300A, 300B, and 300C, the rare earth-containing material LuHₓN_{y} may have a transition, or critical, temperature (T_{c}) for a transition to and/or from a perfect diamagnet (Meissner effect) for temperatures at, near, or above 200 Kelvin at ambient pressure (e.g., approximately 1 atmosphere). In some embodiments, the critical temperature may be at or above 273 Kelvin at ambient pressure. In some embodiments, the critical temperature may be at or above 100 Kelvin at ambient pressure. FIGS. 4A-4C depict the temperature dependent DC electrical resistance data (graph 400A of FIG. 4A) and AC electrical resistance data (graph 400B in FIG. 4B) and the current-voltage (I-V) curves (graph 400C in FIG. 4C) at different temperatures corresponding to a rare earth-containing material such as nitrogen doped lutetium hydride. FIG. 4D depicts graph 400D of superconducting critical temperature (T_{c}) as a function of nitrogen doping contend (y(N)) for LuH_{2.2}N_{y}. Graph 400D depicts T_{c} from the isotropic (dashed lines) and anisotropic (solid lines). The inset shows with filled circles the electron-phonon parameter (λ) and the density of states at EF (N (EF)) with open circles within the harmonic approximation as a function of y(N). Thus, LuHₓN_{y} may have a critical temperature for superconductivity at, near, or above 200 Kelvin at ambient pressure. The superconducting critical temperature may be at or above 273 Kelvin at ambient pressure for LuHₓN_{y} in some embodiments. The superconducting critical temperature may be at or above 100 Kelvin at ambient pressure for LuHₓN_{y} in some embodiments.

Thus, a rare earth-containing materials RHₓD_{y}, such as LuHₓN_{y}, may be used not only for their intrinsic properties, but also to investigate the variation in lattice parameter, stoichiometry, positions of atoms, and other properties of rare earths. The results for LuHₓN_{y} may be used to predict the properties of other rare earth containing materials. As part of this process, RHₓD_{y} is desired to be fabricated and compared to known materials.

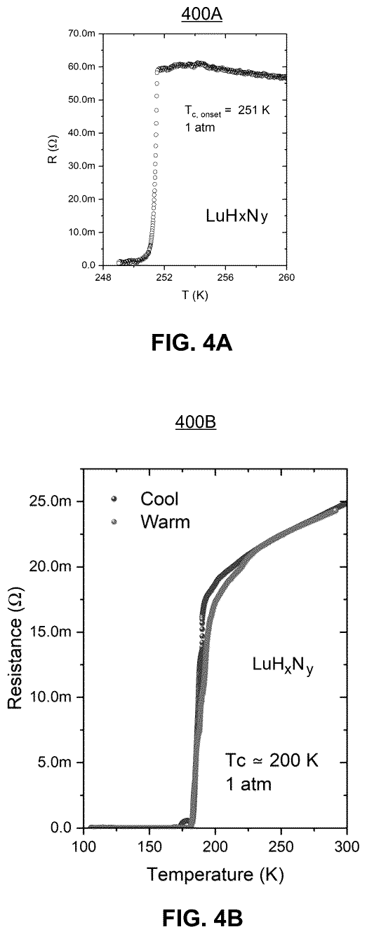

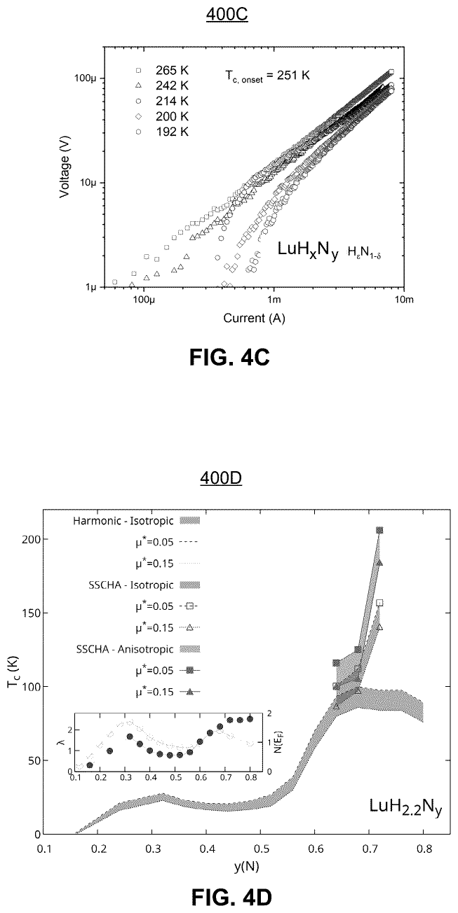

For example, FIG. 5 and FIG. 6 depict embodiments of cells 500 and 600, respectively, of two forms of a rare earth hydride. More specifically, cells 500 and 600 correspond to lutetium hydride. Cell 500 corresponds to LuH₂, while cell 600 corresponds to a cubic form of LuH₃. Cell 500 includes R (FCC) positions 510 (large darker spheres) and tetrahedral positions 520 (small lighter spheres), of which only some are labeled. Similarly, cell 600 includes R (FCC) positions 610 (large darker spheres), tetrahedral positions 620 (small lighter spheres), and octahedral positions 630 (small darker spheres). R positions 510 and 610 correspond to R positions 110. Tetrahedral positions 520 and 620 correspond to tetrahedral positions 120. Octahedral positions 630 correspond to octahedral positions 630. Lattice parameters, d, are also shown. In general, all positions 510, 520, 610, 620, and 630 are occupied by R (Lu) atoms and H atoms. Thus, using the information described herein, such as x-ray diffraction, Raman spectroscopy, other data (e.g., electronic, magnetic, and mechanical data), the effects of dopants, such as N, may be investigated in comparison to undoped versions of the rare earth-containing material. Similarly, other arguably related materials may also be investigated.

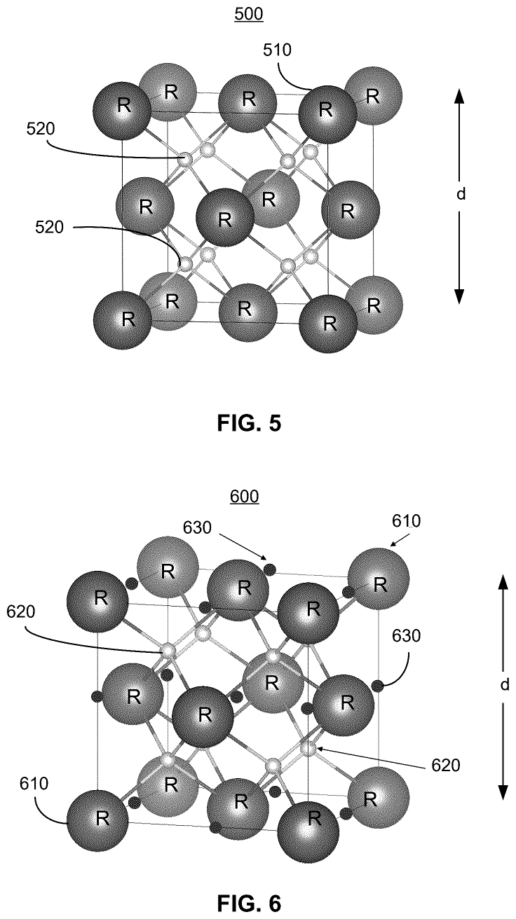

For example, FIG. 7 is a diagram depicting an embodiment cell 700 indicating the crystal structure of an embodiment of a rare earth nitride RD_{z}, such as LuN_{z}, where z<1. Thus, cell 700 may be for sub-stoichiometric LuN. In some embodiments, R and D may be analogous to the materials described for RHₓD_{y} (e.g., R may include materials such Lu, Y, Sc, Tm, and/or Y; D may include N, B, and/or O (generally in smaller amounts)). Cell 700 includes FCC R positions 710 and octahedral positions 730 that are analogous to R positions 110, 510, and 610 and octahedral positions 130 and 630. Octahedral positions 730 are locations of D (e.g., N). If all octahedral positions 730 were filled with D atoms, then the corresponding rare earth-containing material would have the form RD. However, cell 700 corresponds to a sub-stoichiometric rare earth-containing material RD_{z}, such as LuN_{z}, where 0<z<1. Thus, cell 700 is described in the context of LuN_{z} with 0<z<1. For stoichiometric LuN (i.e. where z=1), octahedral sites 730 may be fully occupied. For LuN_{z}, there are vacancies at some octahedral positions 730. However, specific locations of the vacancies are not indicated in cell 700. In a macroscopic sample, composed of a large number of cells 700, there may be some defects. For example, there may be vacancies for which a rare earth atom is missing from particular R position(s) 710 or there are additional R atoms at particular R position(s) 710. However, such defects may not be sufficient to affect the stoichiometry and/or material properties.

In a similar manner to RHₓD_{y}, (e.g., LuHₓN_{y}) corresponding to cell 100, LuN_{z} corresponding to cell 700 may indicate how changes in stoichiometry or other properties result in changes to crystal structure and/or characteristics of rare earth-containing materials. For example, LuN has a lattice parameter of approximately 4.75 to 4.76 Å. As discussed with respect to LuHₓN_{y}, this smaller lattice parameter may be due to the properties of nitrogen and/or the nitrogen interaction with Lu. Although x-ray diffraction may be capable of determining some aspects of the structure of cell 700 (e.g., lattice parameter d), other aspects may not be distinguishable using x-ray diffraction. For example, the locations and/or presence of vacancies for octahedral locations 730 may not be indicated in x-ray diffraction. Thus, LuN_{z} may be studied in a similar manner to RHₓD_{y}, (e.g., LuHₓN_{y}).

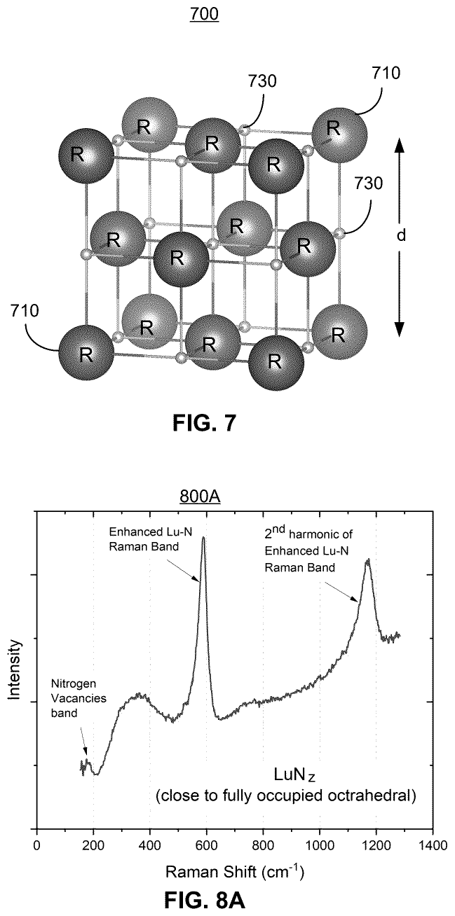

For example, FIGS. 8A-8C depicts graphs 800A, 800B, and 800C including Raman spectra for sub-stoichiometric LuN (LuN_{z}, where z<1). As can be seen in graphs 800A and 800B, peaks indicating the Lu-N Raman band and the second harmonic of the LuN Raman band are indicated. In addition, as can be seen in graphs 800A, 800B, and 800C a nitrogen vacancy band is also indicated near 200 cm⁻¹ for sub-stoichiometric LuN_{z} but not for stoichiometric LuN. The Raman spectra in graphs 800A, 800B, and 800C may also be applied in understanding the properties of LuHₓN_{y}. A comparison of graphs 800A, 800B, and 800C with graph 200D indicates that LuHₓN_{y} and LuN_{z}, have peaks indicating octahedral vacancies near 200 cm⁻¹. Thus, that that y<1 and z<1 for LuHₓN_{y} and for LuN_{z} may be indicated and understood by the Raman spectra. Thus, materials such as RHₓD_{y} (e.g., LuHₓN_{y}) and/or RD_{z} (e.g., LuN_{z}) may be used to investigate the effects of stoichiometry changes on particular rare earth-containing materials and/or to predict or understand characterization of other materials.

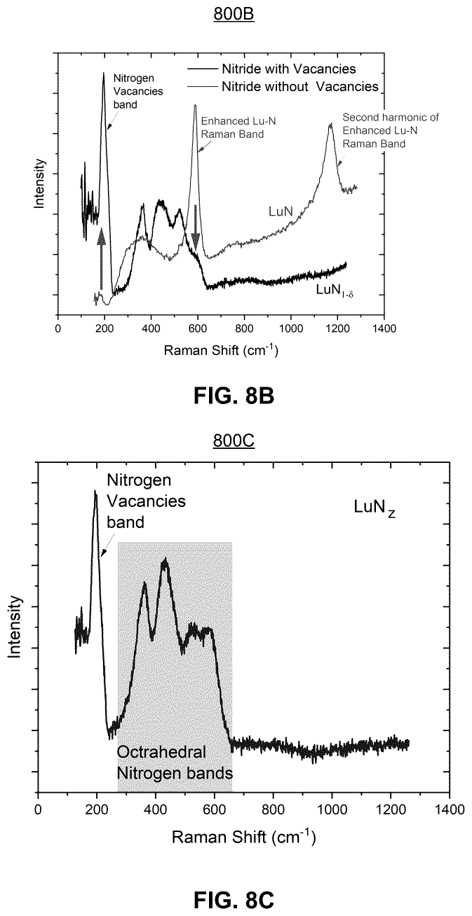

FIGS. 9A-9C depict graphs 900A, 900B, and 900C of magnetic data corresponding to a sub-stoichiometric rare earth-containing material, such as LuN_{z}. Graphs 900A, 900B, and 900C depict magnetic moment versus temperature for LuN_{z} taken using a SQUID magnetometer (e.g., an MPMS SQUID magnetometer). As indicated in graphs 900A, 900B, and 900C, the rare earth-containing material LuN_{z} may have a transition, or critical, temperature (T_{c}) for a transition to and/or from a perfect diamagnet (Meissner effect) for temperatures near 38 Kelvin at ambient pressure (e.g., approximately 1 atmosphere). Thus, LuN_{z} may have a critical temperature for superconductivity near 38 Kelvin at ambient pressure. In such a case, the increase in the critical temperature between LuN_{z} and LuHₓN_{y} may be viewed as the introduction of H facilitating phonons in the rare earth-containing material, which is associated with higher critical temperatures for superconductivity.

Thus, rare earth-containing material RD_{z}, such as LuN_{z}, may be used to investigate the variation in lattice parameter, stoichiometry, positions of atoms, and properties of rare earths. The results for LuN_{z} may be used to predict the properties of other rare earth containing materials. As part of this process, RD_{z} is desired to be fabricated and compared to known materials.

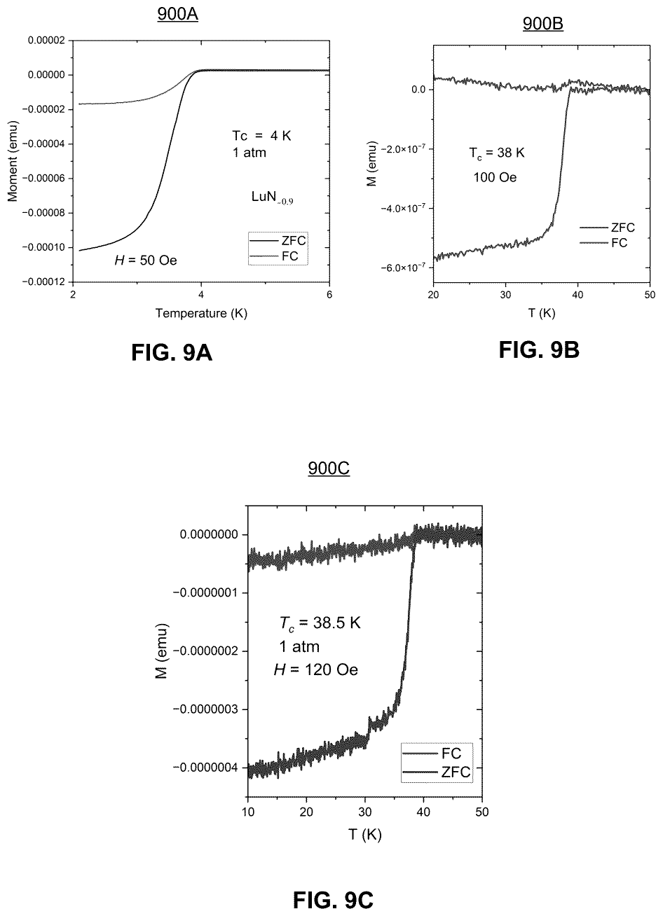

FIG. 10 is a flow chart depicting an embodiment of process 1000 for fabricating a rare earth-containing material such as RHₓD_{y} (e.g., LuHₓN_{y}) and/or RD_{z} (e.g., LuN_{z}). Although processes of method 1000 may be shown in a particular order, another order (e.g., in parallel) may be used. Further, steps of method 1000 may include substeps.

Precursor material(s) used in fabricating the rare earth-containing material(s) are provided, at 1002. In some embodiments, 1002 may include simply obtaining pre-made precursor material(s). In some embodiments, precursor material(s) for the rare earth-containing material(s) are synthesized. For example, LuH₂ (cubic) and LuH₃ (hexagonal) are stable at ambient. At 1002, it may be desirable to form LuH₂ and/or LuH₃.

In some embodiments, synthesis at 1002 may occur in a furnace having a particular configuration and/or limitations. The furnace might be desired to be capable of monitoring and controlling the elements within the system and the environment to which the elements are exposed. For example, a furnace having a quartz chamber may be desired to reduce the interaction of the chamber with the material(s) used. Other chambers having other material(s) which may not outgas or otherwise affect preparation of the precursor material(s) and/or rare earth-containing material(s) may be used. The furnace may be desired to have temperature monitoring and control (e.g., the rate for heating and/or cooling as well as the desired range of temperatures). The chamber may also be configured to withstand the desired pressures. For example the chamber may be used with both greater than atmospheric pressure and less than atmospheric pressure (e.g., vacuum) of the desired ranges. Further, the ability to characterize the material(s) produced while still in the furnace (e.g., in situ) may be desired. Additional processing of the precursor material(s) may also be performed at 1002. For example, ball milling (to form a finer powder) and/or other processes that may make the precursor material(s) more homogeneous and/or improve yield for the rare earth-containing material(s) may be desired.

Using the precursor material(s), material(s) including at least one rare earth are provided, at 1004. In some embodiments the material includes the rare earth(s), hydrogen (H), and/or dopant(s) (D) (e.g., LuHₓN_{y}). In some embodiments, 1004 includes providing the material that includes the rare earth(s) and the dopant(s) (e.g., LuN_{z}). In some embodiments, 1004 may be performed in the same furnace as 1002 (assuming the precursor material(s) are synthesized). In some embodiments, 1004 may be performed using other equipment. For example, 1004 may be performed using a thin film deposition system (e.g., chemical vapor deposition (CVD), sputtering, atomic layer deposition (ALD), and/or molecular beam epitaxy (MBE).

For example, 1002 may include purchasing or otherwise obtaining already available Lu, LuH₂, LuH₃, or stoichiometric LuN. In another example, LuH₂ and/or LuH₃ may be synthesized from Lu. In some embodiments, formation of LuH₃ at 1002, this may occur using the formula:

Lu(s)+H₂(g)->LuH₃(s)

In such embodiments, pure Lu may be placed in a high-pressure reactor. Hydrogen gas (H₂) may be provided at greater than 500 psi and temperatures in the range of 250° C. through 350° C. (e.g., nominally 300° C.) to convert the Lu to hcp-LuH₃. In some embodiments, pure hydrogen gas and oxygen scavengers may be employed to reduce or prevent oxidation. In some embodiments, the above reaction may be used to synthesize LuH₃ in a tube furnace using excess H₂ and temperatures below 250° C. (and above, e.g., 100° C.). Other techniques may be used to form LuH₃.

In some cases, formation (or purchase) of LuH₃ may be followed by the reaction:

2LuH₃(s)->2LuH₂(s)+H₂(g)

The reaction may be performed above the decomposition temperature of LuH₃ (approximately 300° C.) and below the disassociation temperature of LuH₂ (approximately 720° C.) at ambient pressure. For example, LuH₃ may be placed in a vacuum or inert atmosphere. This may reduce or prevent oxidation. LuH₃ may be held in a temperature range of 350° C. through 650° C., during which hydrogen is emitted by the solid. The emitted hydrogen gas is also evacuated to prevent recombination to LuH₃. Thus, LuH₂ may be formed via LuH₃.

Similarly, the following reaction might be used:

Lu(s)+H₂(g)->LuH₂

To do so, Lu may be placed in hydrogen gas at particular pressure(s) and the temperature elevated. The temperature used to transform Lu to LuH₂ may depend upon the pressure and vice versa. For example, a pressure of greater than 250 mbar and a temperature greater than 560° C. and not more than 600° C. (or not more than the disassociation temperature of LuH₂) may be used to convert Lu to LuH₂. In some embodiments, additional hydrogen gas is reintroduced to adjust the stoichiometry of the LuH₂ produced. Thus, the LuH₂ may be stoichiometric, sub-stoichiometric (LuH_{2-β}) or super-stoichiometric (LuH_{2+α}). For example, Lu may be placed in a vessel (e.g., a quartz furnace) with hydrogen gas. The temperature may be elevated and the pressure monitored. A significant drop in pressure indicates that hydrogen gas has been taken up by the Lu. The temperature may remain elevated and hydrogen gas reintroduced. As more hydrogen gas is taken, the pressure drops. Once temperature and pressure remain constant, the reaction that converts Lu to LuH₂ is completed. Thus, (sub-stoichiometric, stoichiometric, or super-stoichiometric) LuH₂ may be formed directly from Lu.

Thus, at 1002, LuH₂ (from Lu) may be synthesized as precursor material(s) with or without using LuH₃ as an intermediary. In some cases, the precursor material(s) might be sub-stoichiometric (e.g., due to additional vacancies) or super-stoichiometric (e.g., due to additional atoms). Using the precursor material(s), the desired rare earth-containing material(s) may be formed, at 1004. For example, LuHₓN_{y} or LuN_{z} may be formed from LuH₂ and/or LuH₃.

Using method 1000 the desired rare earth-containing material(s) may be fabricated. In some embodiments, method 1000 results in the desired rare earth-containing material(s) along with other materials. For example, some amount of the precursor material may remain. For smaller pieces of the precursor material (e.g., a powder as opposed to bulk pieces or a ball milled fine powder as opposed to a powder), a larger fraction may be converted to the desired rare earth-containing material (e.g., sub-stoichiometric lutetium nitride or nitrogen doped lutetium hydride). In some embodiments, the majority of the precursor material is converted to the desired rare earth-containing material. Stated differently, the rare earth-containing material may be the majority phase. In some embodiments, the rare earth-containing material might be in isolation (e.g., for a thin film). All or substantially all of the material formed is the desired rare earth-containing material. Consequently, the rare earth-containing material(s) may be used as described herein (e.g., for investigating the structure, stoichiometry, and characteristics of the material) and/or in technological applications.

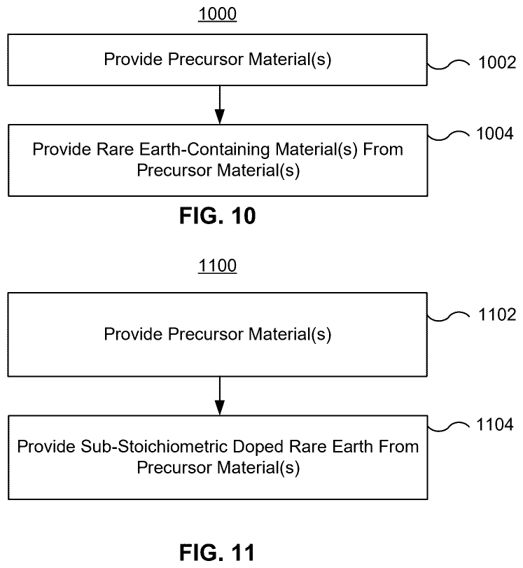

FIG. 11 is a flow chart depicting an embodiment of method 1100 for fabricating rare earth-containing material. In particular, method 1100 may be used in providing RD_{z} (e.g., LuN_{z}). Although processes of method 1100 may be shown in a particular order, another order (e.g., in parallel) may be used. Further, steps of method 1100 may include substeps. Method 1100 is described in the context of LuN_{z}. Moreover, method 1100 may be viewed as a particular implementation of method 1000.

At 1102, the precursor material(s) are provided. In some embodiments, this includes formation or obtaining LuH₂, Lu, or LuH₃. LuH₂ and/or LuH₃ may be formed as described with respect to 1002.

At 1104, the precursor material(s) are converted to LuN_{z}. In some embodiments, 1104 may be analogous to 1004. The particular process(es) used for 1104 depend upon the precursor material(s). For example, if the precursor material used in Lu, then LuN_{z} may be formed at 1104 by exposing Lu to nitrogen gas at very high temperatures (e.g., greater than 1650° C. If the precursor material is LuH₂, then the following reactions may be used:

LuH₂(s)+N₂(g)->Lu(s)+H₂(g)+N₂(g)

2Lu(s)+H₂(g)+N₂(g)->2LuN+H₂(g)

Thus, a two-step process may be used for 1104. In such an embodiment, LuH₂ is decomposed to Lu (e.g., at temperatures above the decomposition temperature of LuH₂, for example at temperatures above 720° C., at or above 900° C., or at or above 1100° C.). The Lu may then be converted to LuN_{z}.

If LuH₃ is the precursor material, then the following reactions may be used at 1104.

2LuH₃(s)+N₂(g)->2LuH₂(s)+H₂(g)+N₂(g)

2LuH₂(s)+N₂(g)->2LuNₓ+2H₂(g)

In the first reaction, LuH₃ and nitrogen are exposed to temperature(s) above the disassociation temperature of LuH₃ (e.g., above 300° C.) to form the intermediary LuH₂. In the second reaction, the hydride LuH₂ is converted to LuN_{z}. The second reaction may be considered analogous to the two-step conversion described for the precursor material LuH₂.

Thus, using method 1100 the desired rare earth-containing material(s), RN_{z}, may be fabricated. In some embodiments, method 1000 results in the desired rare earth-containing material(s) along with other materials. For example, some amount of the precursor material may remain, as discussed for method 1000.

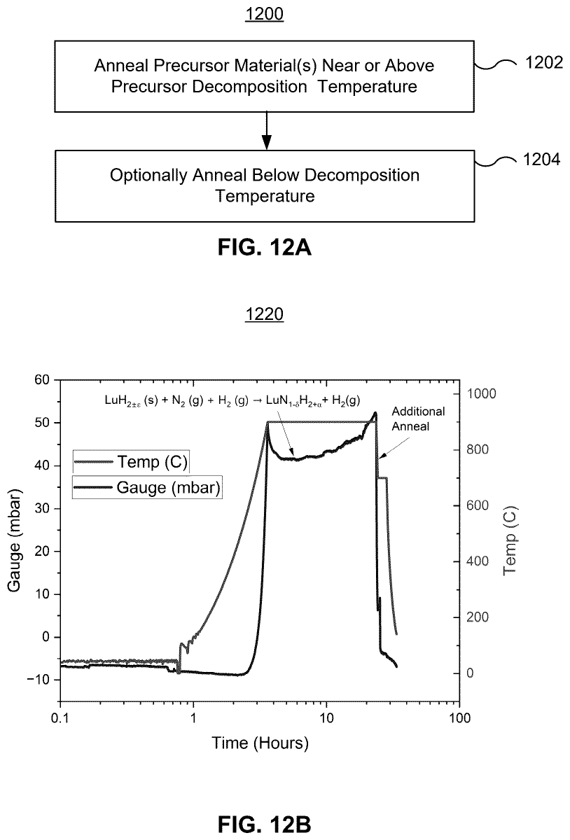

FIGS. 12A-12D depict embodiments of a method for fabricating a rare earth-containing material such as RHₓD_{y} (e.g., LuHₓN_{y}) from precursor material(s). FIG. 12A is a flow chart depicting an embodiment of process 1200 for fabricating a rare earth-containing material such as RHₓD_{y} (e.g., LuHₓN_{y}) from precursor material(s). Method 1200 may be considered analogous to step 1004 of method 1000. FIGS. 12B, 12C, and 12D are graphs depicting pressure and temperature in embodiments of method 1200. Although processes of method 1200 may be shown in a particular order, another order (e.g., in parallel) may be used. Further, steps of method 1200 may include substeps.

At 1202, the precursor material(s) are annealed near or above the decomposition temperature of the precursor material(s). For example, LuH₂ may be annealed in nitrogen gas at 900 C (e.g., above the decomposition temperature) or near 750 C (e.g., near/above the decomposition temperature of LuH₂). Similarly, LuH₃ may be annealed in nitrogen gas at similar temperatures. The pressure and temperature of the system may be monitored. Drops in the pressure (or a reduction in the rate of increase of temperature) indicate a change in stoichiometry. For example, the decrease in pressure may mean that nitrogen is taken up by the solid or a change in the solid from LuH₃ to LuH₂. Thus, at 1202, the following reaction may be considered to take place:

LuH_{2±ε}+N₂(g)+H₂(g)->LuN_{1-δ}H_{2+α}+N₂(g)+H₂(g)

In the above reaction, α, δ, and ε indicate that the materials used and/or formed may be sub-stoichiometric and/or super-stoichiometric.

In some embodiments, an additional anneal at or near the decomposition temperature of a precursor material (e.g., LuH₂) may be performed, at 1204. In this context, a precursor material may include an intermediate (e.g., where precursor material LuH₃ is converted to LuH₂ as part of the process).

For example, FIG. 12B includes graph 1220 indicating one embodiment of method 1200 in which LuH₂ (e.g., LuH_{2±ε}) is the precursor material. At 1202, the precursor material is heated above the decomposition temperature (e.g., approximately 900° C. in this embodiment). A drop in pressure indicates the formation of a nitrogen doped lutetium hydride. Also indicated in graph 1220 is an additional anneal at or near 700° C.-750° C., at 1204. In such an embodiment 1204 may be used to adjust the stoichiometry of the final rare earth-containing material.

In another example, FIG. 12C includes graph 1230 indicating one embodiment of method 1200 in which LuH₃ (e.g., LuH_{3-γ}) is the precursor material. At 1202, the precursor material is heated above the decomposition temperature (e.g., approximately 900° C. in this embodiment). A drop in rate of increase of pressure indicates the formation of LuH₂ from LuH₃ (e.g., LuH_{2±ε} from LuH_{3±γ}). The drop in pressure indicates the formation of a nitrogen doped lutetium hydride. Also indicated in graph 1230 is an additional anneal at or near 720° C.-750° C., at 1204. In such an embodiment 1204 may be used to adjust the stoichiometry of the final rare earth-containing material.

In another example, FIG. 12D includes graph 1240 indicating one embodiment of method 1200 in which LuH₃ (e.g., LuH_{3-γ}) is the precursor material. At 1202, the precursor material is heated above the decomposition temperature (e.g., approximately 750° C. in this embodiment). A drop in rate of increase of pressure indicates the formation of LuH₂ from LuH₃ (e.g., LuH_{2±ε} from LuH_{3-γ}). The drop in pressure indicates the formation of a nitrogen doped lutetium hydride. In this embodiments, 1204 may be omitted.

Thus, using method 1200 the desired rare earth-containing material(s), RHₓN_{y}, may be fabricated. In some embodiments, method 1200 results in the desired rare earth-containing material(s) along with other materials. For example, some amount of the precursor material may remain, as discussed for method 1000.

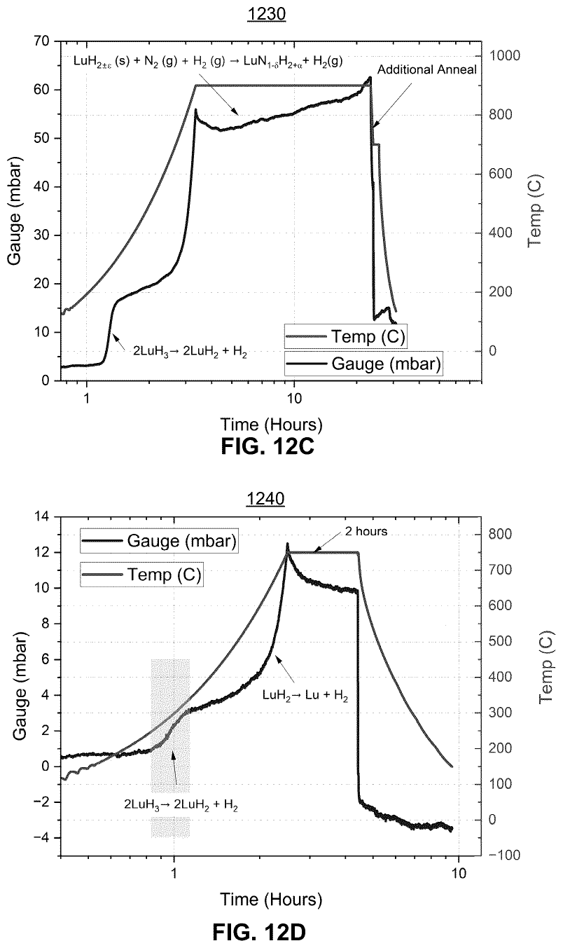

FIG. 13 is a flow chart depicting an embodiment of process 1300 for fabricating a rare earth-containing material such as RHₓD_{y} (e.g., LuHₓN_{y}) and/or RD_{z} (e.g., LuN_{z}) from precursor material(s). Although processes of method 1300 may be shown in a particular order, another order (e.g., in parallel) may be used. Further, steps of method 1300 may include substeps.

At 1302, the precursor material(s) are annealed near or above the decomposition temperature of the precursor material(s). For example, LuH₂ may be annealed in nitrogen gas at 900 C (e.g., above the decomposition temperature) or near 750 C (e.g., near/above the decomposition temperature of LuH₂). Alternatively, LuH₃ may be annealed in nitrogen gas at similar temperatures. This heating may be considered to remove hydrogen from the precursor material(s).

At 1304, a nitrogen-containing material may be added. For example, potassium nitride or sodium nitride may be added. Heat treating the substances allows the nitrogen to be from the nitride-containing material to be added to the heat-treated precursor material(s). In another, analogous embodiment, the precursor material(s) may include LuN, which is heat treated at 1302. Hydrogen or a hydrogen-containing material may be added at 1304 to allow hydrogen into the heat-treated precursor material(s).

Thus, using method 1300 the desired rare earth-containing material(s), RHₓN_{y}, may be fabricated. In some embodiments, method 1300 results in the desired rare earth-containing material(s) along with other materials. For example, some amount of the precursor material may remain, as discussed for method 1000.

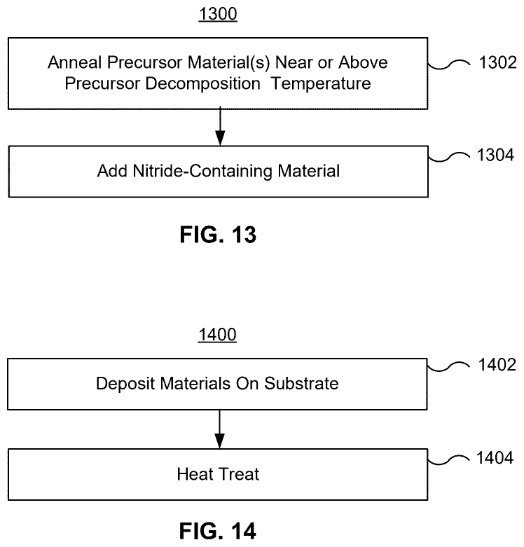

FIG. 14 is a flow chart depicting an embodiment of method 1400 for fabricating precursor material(s) rare earth-containing material, such as RHₓD_{y} (e.g., LuHₓN_{y}) and/or RD_{z}(e.g., LuN_{z}) from precursor material(s). Although processes of method 1400 may be shown in a particular order, another order (e.g., in parallel) may be used. Further, steps of method 1400 may include substeps. Method 1400 may be used in providing a thin film including RHₓD_{y} (e.g., LuHₓN_{y}) and/or RD_{z} (e.g., LuN_{z}). Method 1400 may commence after precursor material(s) are obtained, for example at 1002. Thus, method 1400 may be considered to be one embodiment of 1004.

At 1402, constituents for the desired rare earth-containing material are deposited on a substrate in the appropriate atmosphere. In some embodiments, 1402 may include process(es) such as chemical vapor deposition (CVD), atomic layer deposition (ALD), sputtering, and/or other techniques for growing thin films. In some embodiments, a multilayer is deposited at 1402. For example, layers having different constituents may be alternately deposited. In some embodiments, materials are co-deposited at 1402.

At 1404, the material(s) may be heat treated. In some embodiments, 1404 may be interleaved with or performed in parallel with 1402. In other embodiments, 1404 may be performed after 1402. For example, 1404 may include annealing the material(s) after deposition, annealing portions of the materials (e.g., sublayers of a multilayer or a thinner portion of a layer that includes co-deposited materials), heating the substrate and/or deposition system before, during or after deposition, and/or other techniques.

Using method 1400 the desired rare earth-containing material(s), RHₓN_{y} (e.g., LuHₓN_{y}) and/or RD_{z} (e.g., LuN_{z}) might be fabricated. In some embodiments, method 1400 results in the desired rare earth-containing material(s) in isolation (e.g., the majority or only phase) on the substrate. Thus, using method(s) 1000, 1100, 1200, 1300, and/or 1400, the material(s) having the desired composition may be fabricated for uses such as investigating the properties of rare earth-containing materials and/or technological applications.

Although the foregoing embodiments have been described in some detail for purposes of clarity of understanding, the invention is not limited to the details provided. There are many alternative ways of implementing the invention. The disclosed embodiments are illustrative and not restrictive.

What is claimed is:

1. A system, comprising:
a material including
at least one rare earth (R);
hydrogen (H); and
at least one dopant (D), the material including R, H, and D in a ratio of 1:x:y,
where x is greater than 2 and less than 3, and y is at least 0.4 and less than 1.

2. The system of claim 1, wherein R is lutetium and D is nitrogen.

3. The system of claim 2, wherein the material has a crystal structure and a stoichiometry RHₓD_{y}.

4. The system of claim 3, wherein x is at least 2.1 and not more than 2.3 and y is at least 0.7 and not more than 0.8.

5. The system of claim 3, wherein the crystal structure has face-centered cubic positions, tetrahedral positions, and octahedral positions; and
wherein the face-centered cubic positions include R atoms, the tetrahedral positions include H atoms, and the octahedral positions include both the H atoms and D atoms.

6. The system of claim 5, wherein a portion of at least one of the octahedral positions, the face-centered cubic positions, or the tetrahedral positions have at least one vacancy.

7. The system of claim 3, wherein the material has a lattice parameter depending on x and y.

8. The system of claim 2, wherein the material is present with at least one additional material including the at least one rare earth.

9. The system of claim 8, wherein the material includes at least one of a powder or a thin film residing on a substrate and having a thickness of at least ten nanometers and not more than three micrometers.

10. The system of claim 2, further comprising:
at least one additional material, the at least one additional material including at least one of O and Si.

11. A system, comprising:
a material including
at least one rare earth (R); and
nitrogen (N); wherein the material has a crystal structure and a stoichiometry
including RN_{y}, where y is greater than zero and less than one.

12. The system of claim 11 wherein y is greater than 0.6 and less than 0.9.

13. The system of claim 11, wherein the crystal structure has face-centered cubic positions and octahedral positions; and
wherein the face-centered cubic positions include R atoms and the octahedral positions include N atoms.

14. The system of claim 13, wherein a portion of the octahedral positions have at least one vacancy.

15. A method, comprising:
providing at least one precursor material; and
providing, using the at least one precursor material, a material including at least one rare earth (R), hydrogen (H); and at least one dopant (D), the material including R, H, and D in a ratio of 1:x:y, where x is zero or greater than 2 and less than 3, and y is at least 0.4 and less than 1, and wherein D is nitrogen (N) for x=0.

16. The method of claim 15, wherein R is lutetium, D is nitrogen and the at least one precursor material is selected from LuH₂ or LuH₃.

17. The method of claim 15, wherein the providing the material includes:
annealing the at least one precursor material in a D-containing gas at at least one temperature greater than a decomposition temperature of the at least one precursor material.

18. The method of claim 17, wherein x is greater than 2 and less than 3 and wherein the providing the material further includes:
reducing the temperature to within a temperature range below the decomposition temperature of the at least one precursor material, the temperature range being greater than one is hundred degrees Celsius and less than the decomposition temperature; and
annealing at one or more temperatures within the temperature range.

19. The method of claim 15, wherein the providing the at least one precursor material includes obtaining at least one premade precursor material.

20. The method of claim 15, wherein the providing the material further includes:
depositing the material using the at least one precursor material as a deposition source.
